(19) United States
(12) Patent Application Publication
(10) Pub. No.: US 2004/0209464 A1
(43) Pub. Date: Oct. 21, 2004

(54) Plating method and plating apparatus

(76) Inventors: Keiichi Sawai, Hiroshima (JP); Osamu Miyake, Okayama (JP)

Correspondence Address: Nixon & Vanderhye, 8th Floor, 1100 North Glebe Road, Arlington, VA, 22201-4714, US

(21) Appl. No.: 10/484,630

(22) PCT Filed: Jul. 24, 2002
(86) PCT No.: PCT/JP02/07464

(30) Foreign Application Priority Data
Jul. 25, 2001 (JP) 2001-225127

(51) Int. Cl. H01L 21/44

(52) U.S. Cl. 438/678

(57) ABSTRACT

A shielding plate (7) having an opening section is inserted between a semiconductor substrate (substrate to be plated) (4) and an anode electrode (5). An outer edge of the opening section of the shielding plate (7) is smaller than an outer edge of the semiconductor substrate (4) by a predetermined distance. The predetermined distance is set so that a difference between a size of the semiconductor substrate (4) and a size of the opening section has an optimum value that enables a plating film (bump electrode) to have a uniform thickness on an entire surface of the semiconductor substrate (4). With this, it is possible to provide a plating method and plating device capable of forming a plating film having almost no variation in thickness by providing a shielding plate having a simple shape, without increasing the cost of the plating device.

### TECHNICAL FIELD

The present invention relates to a plating method and plating device employing an electric field plating method, and in particular to a plating method and plating device for forming a plating film having a uniform thickness on a material to be plated.

### BACKGROUND ART

In these years, electronic devices such as portable digital assistants have become smaller in size and lighter in weight. In response to this, compactness, lightness in weight, and high packaging density have been required for semiconductor integrated circuits mounted on these electronic devices.

A commonly used method to achieve the compactness and high packaging density of semiconductor integrated circuits, etc. (hereinafter referred to as semiconductor devices) is to use a packaging protrusive electrode (so-called bump electrode). With this method, plating technique is applied to form a bump electrode of gold (Au) on a predetermined position on a surface of the semiconductor device, and the bump electrode is used to directly package the semiconductor device on a packaging substrate.

The bump electrode is formed in the following manner. First, photo resist is applied to a surface of a semiconductor substrate on which many semiconductor devices have been mounted. Next, the photo resist film is removed at a portion where the bump electrode is to be formed, so as to reveal a base metal film that has been layered on the semiconductor substrate. After this, the semiconductor substrate is immersed in plating liquid, and then plating metal such as gold (Au) is deposited using plating technique on the exposed portion of the base metal film at the opening portion of the photo resist film, so that the bump electrode is formed.

There are two plating methods, namely an electrolytic plating method and an electroless plating method. The bump electrode is generally formed using the electrolytic plating method. The electrolytic method has the steps of connecting a cathode electrode with a substrate to be plated, immersing the substrate and an anode electrode in plating liquid so that the substrate and the anode electrode face each other, and applying a predetermined DC current so as to deposit plating metal on a predetermined portion of the substrate. The electrolytic plating method has advantages such that a growth rate of plating is remarkably more rapid than in the electroless plating method, and the combination of the base metal and plating liquid is more flexible. With this, it is possible to easily form a plating layer having a thickness of several tens μm required for the bump electrode.

Further, in the method to use the bump electrode to package the semiconductor device on the packaging substrate as described above, it is indispensable that the height of the bump electrode formed on the surface of the semiconductor device, namely the plating thickness, is uniform within the semiconductor substrate as well as within the semiconductor device. This is to obtain the strength for connecting the bump electrode with the packaging substrate, and the connecting reliability of the packaging substrate.

To form a plating film having a uniform thickness within the substrate, it is necessary that the plating metal constantly has a predetermined ion concentration in the vicinity of the surface of the substrate to be plated. For this reason, used is a method to stir the plating liquid, or a method to constantly replace plating liquid around the substrate by causing the plating liquid to flow at a predetermined speed.

In the electric field plating method, lines of electric force in the plating bath are parallel to one another and perpendicular to the substrate and anode electrode, and substantially have a uniform density on the central portion of the substrate. However, the lines of electric force tend to concentrate on peripheral portions of the substrate due to an edge effect, etc. Accordingly, plating grows faster on the peripheral portions of the substrate than on the central portion of the substrate, thus causing a problem such that plating is thicker on the peripheral portions of the substrate. The nonuniform plating that occurs in the electric field plating method cannot be sufficiently prevented by the foregoing method to replace plating liquid around the substrate by stirring the plating liquid, etc.

For this reason, as a method to form a plating film having a uniform thickness within the substrate in the electric field plating method, there is a method to control electric field on the surface of the substrate by inserting a shielding plate having a hole of a predetermined shape between the substrate and the anode electrode.

Japanese Unexamined Patent Publication No. 2000-345384 (Tokukai 2000-345384, published on Dec. 12, 2000) discloses a technique to form a plating film having a uniform thickness. In this method, a shielding plate having many small-diameter holes is inserted between a substrate and an anode electrode, so as to adjust the flow of plating liquid. But this method requires extremely complicated processing for optimizing the size and arrangement of the small-diameter holes to be formed on the shielding plate.

Further, Japanese Unexamined Patent Publication No. 11-246999 (Tokukaihei 11-246999, published on Sep. 14, 1999) discloses a technique to form a plating film having a uniform thickness within the substrate. In this technique, a shielding plate having an opening section is inserted between the substrate and the anode electrode so as to prevent the concentration of the lines of electric force around the peripheral portions of the substrate.

FIG. 5 is a view schematically showing a plating device disclosed in Tokukaihei 11-246999. The electrolytic plating device 11 is so arranged that a plating bath 12 is filled with plating liquid 13. In the plating liquid 13, a substrate 14 and an anode electrode are provided to face each other. Further, a power source 16 applies a DC voltage to the substrate 14 and the anode electrode 15. A shielding plate 17 is provided between the substrate 14 and the anode electrode.

FIG. 6 is a plan view showing an example of the shielding plate 17 disclosed in Tokukaihei 11-246999. Using a mechanism similar to lens diaphragm, the shielding plate 17 can change the size of an opening 17a that is provided at the center of the shielding plate 17. Further, Tokukaihei 11-246999 also discloses a method to change the size of the opening by inserting and pulling out a plurality of shielding plates each having an opening section of a different diameter.

In the method disclosed in Tokukaihei 11-246999, changes in electric resistance of a conductive film that is formed on the surface of the substrate are monitored, and the size of the opening section of the shielding plate is changed (the diaphragm is opened or shut, or the shielding plates are inserted and pulled out) in accordance with the changes in electric resistance. This improves the uniformity of the thickness of the plating film within the substrate.

However, the method of Tokukaihei 11-246999 has the following problems.

First, if the shielding plate is arranged to have the opening section similar to lens diaphragm, it is possible to change the diameter of the opening section, but it is difficult to repeatedly achieve one specific diameter of the opening section in each plating operation. Note that, if a click stop mechanism is used to adjust the diaphragm, the repeatability of the diameter improves, but the mechanism becomes complicated. Further, if the plurality of shielding plates each having an opening section of a different diameter are used, the repeatability of the diameter improves because each of the opening sections of the shielding plates has a specific diameter, but many shielding plates are required.

Further, to form a plating film having a uniform thickness within the substrate, it is necessary to constantly monitor changes in electric resistance of the conductive film that is formed on the surface of the substrate, and change the size of the opening section of the shielding plate in accordance with the changes in electric resistance. This requires means for monitoring changes in electric resistance of the conductive film, and means for changing the size of the opening section of the shielding plate.

As described above, if changes in electric resistance of the conductive film that is formed on the surface of the substrate are manually monitored, and the diameter of the opening section of the shielding plate are manually changed in accordance with the changes in electric resistance, the operator is required to perform complicated processing. Further, it is of course possible to automate the means for monitoring changes in electric resistance of the conductive film and the means for changing the size of the opening section of the shielding plate, but this obviously costs much.

In order to solve the foregoing problems, the present invention has an object to provide a plating method and plating device capable of forming a plating film having almost no variation in thickness by providing a shielding plate having a simple shape, without providing means for monitoring changes in electric resistance of the conductive film and means for changing the size of the opening section of the shielding plate.

### DISCLOSURE OF INVENTION

In order to solve the foregoing problems, a plating method of the present invention that includes the steps of (i) causing a target substrate to be a cathode electrode, (ii) immersing the target substrate and an anode electrode in a plating liquid that fills a plating bath so that the target substrate and the anode electrode substantially face each other in parallel, and (iii) forming a plating film on the target substrate using an electrolytic plating method is arranged so that a shielding plate having an opening section is inserted between the target substrate and the anode electrode; and an outer edge of the opening section is smaller than an outer edge of the target substrate by a predetermined distance, the predetermined distance being set so that a difference between a size of the target substrate and a size of the opening section has an optimum value that enables the plating film to have a uniform thickness entirely on a surface of the target substrate.

Here, the present invention is based on the discovery as described below. In the plating method, in order to form a plating film having a uniform thickness on the entire surface of the substrate to be plated, an optimum value of the opening section of the shielding plate is given using a fixed value. The fixed value is a difference between the size of the substrate to be plated and the size of the opening section of the shielding plate, irrespective of the size of the outer edge of the substrate to be plated.

With this arrangement, the outer edge of the opening section of the shielding plate is smaller than the outer edge of the substrate to be plated by a predetermined distance, and the predetermined distance is set so that the difference between the size of the substrate to be plated and the size of the opening section is the fixed value. With this, special operation such as the size adjustment of the opening section is not required for preparing a shielding plate having an opening section whose size is optimally set with respect to a substrate to be plated whose size is specified. Therefore, it is possible to easily prepare the optimum shielding plate.

By carrying out the plating processing using the shielding plate having an opening section whose size is optimally set, it is possible to form a plating film having almost no variation in thickness within the substrate to be plated. Here, there is no need to monitor changes in electric resistance during the plating, or to adjust or replace the shielding plate, etc. This remarkably reduces the cost compared with the conventional art.

For a fuller understanding of the nature and advantages of the invention, reference should be made to the ensuing detailed description taken in conjunction with the accompanying drawings.

### BRIEF DESCRIPTION OF DRAWINGS

FIG. 1 is an explanatory diagram schematically showing an arrangement of an electric field plating device in accordance with an embodiment of the present invention.

FIG. 2 is a graph showing the relationship between (A) a difference between a diameter of an opening section of a shielding plate and a wafer diameter of a semiconductor substrate and (B) the within-plane uniformity of the semiconductor substrate, in a case where the electric field plating device forms a bump electrode on the semiconductor substrate by plating processing.

FIG. 3 is a plan view showing an example of the shape of a shielding plate used in the electric field plating device.

FIG. 4 is an explanatory diagram showing the relationship between a size of a substrate to be plated and a size of an opening section of a shielding plate, in a case where the substrate to be plated has a rectangular shape.

FIG. 5 is an explanatory diagram schematically showing an arrangement of a conventional electric field plating device.

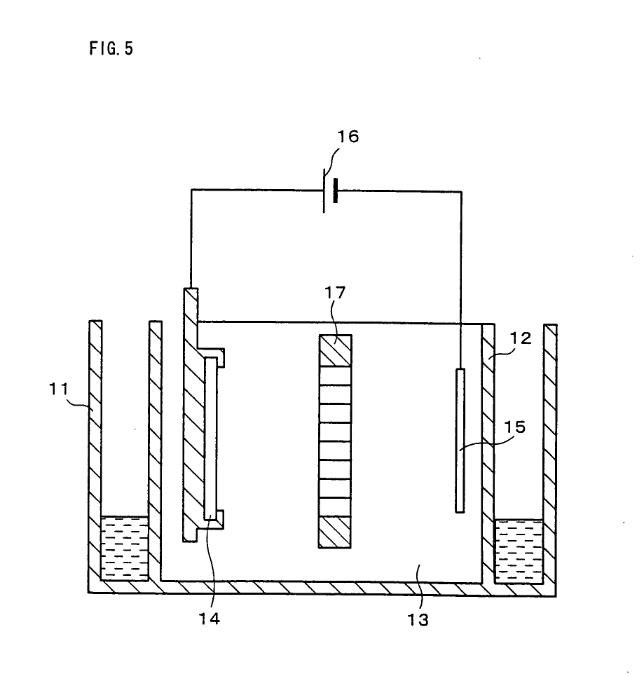

FIG. 6 is an explanatory diagram showing an arrangement of a shielding plate used in the conventional electric field plating device.

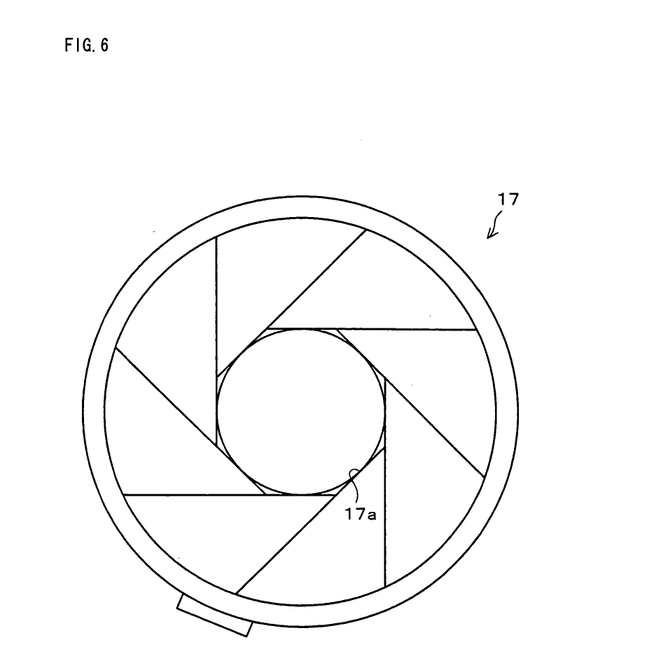

### BEST MODE FOR CARRYING OUT THE INVENTION

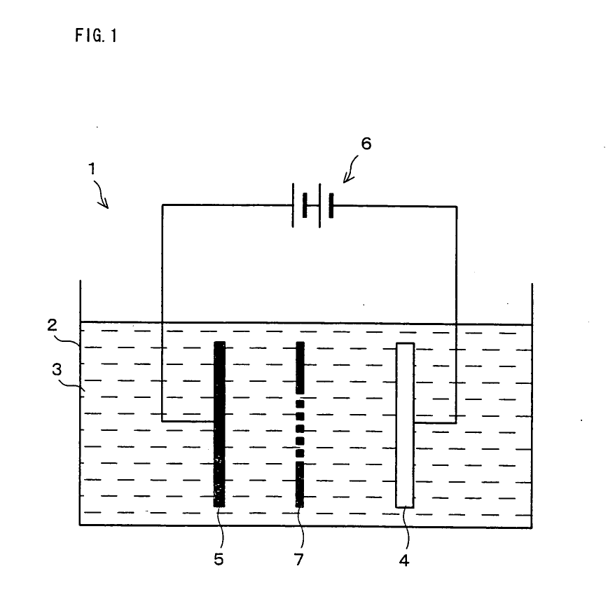

The following will explain an embodiment of the present invention with reference to FIGS. 1 through 4. Note that, the present invention is not limited to this embodiment.

As an example of a plating device to which the present invention is applied, the following explanation employs an electric field plating device used for manufacturing a semiconductor integrated circuit on which a bump electrode is formed using gold plating. Further, the semiconductor integrated circuit is manufactured under the same conditions in the same manner as in the manufacturing of a typical semiconductor integrated circuit.

FIG. 1 schematically shows an arrangement of an electric field plating device of the present embodiment. The electrolytic plating device 1 is so arranged that a plating bath 2 is filled with plating liquid 3. In the plating liquid 3, a semiconductor substrate 4 as a cathode electrode and an anode electrode 5 are provided to face each other. Further, a power source 6 applies a DC voltage to the semiconductor substrate 4 and the anode electrode 5. A shielding plate 7 is provided between the semiconductor substrate 4 and the anode electrode.

Note that, the electrolytic plating device 1 is provided with many other components such as an inlet and outlet for allowing the plating liquid to flow into and flow out of the plating bath 2, for example. Here, arrangements irrelevant to the features of the present invention are omitted from the drawing for simplicity.

First, the following will explain a method for manufacturing a semiconductor integrated circuit using the electric field plating device 1 of the present invention, namely, steps of forming a bump electrode on the semiconductor substrate 4 using gold (Au) plating.

The semiconductor substrate 4, which is used as a substrate to be plated (target substrate) in the present embodiment, is arranged to mount a plurality of semiconductor integrated circuits, and is manufactured in the steps as described below. The steps in the following explanation, however, are only an example, and the present invention is not limited to this.

First, an insulating film such as SiO₂ is layered to have a predetermined thickness on an entire surface of a silicon wafer having a diameter of six inches (approximately 150 mm), for example. Then, photolithography and insulating film etching are used to remove a predetermined portion of the insulating film.

Next, a metal thin film such as Al—Si is layered to have a thickness of approximately 1 μm on the entire surface of the wafer. Then, photolithography and metal thin film etching are used to form a pad electrode which is an output and input terminal. Here, the pad electrode has a size of approximately 60 μm×110 μm. Further, also formed here is wiring for mutually connecting elements such as transistors that are mounted on the surface e of the wafer.

Next, an insulating film such as a SiN film, as a surface protection film, is layered to have a thickness of approximately 0.6 μm on the entire surface of the wafer. Then, photolithography and insulating film etching are used to remove a predetermined portion of the surface protection film, namely a portion of the surface protection film that is on the pad electrode, so as to reveal the pad electrode. The opening portion of the surface protection film has a size of approximately 30 μm×80 μm.

Next, a metal thin film is layered to have a predetermined thickness on the entire surface of the wafer. The metal thin film prevents the reaction between (A) Au with which the bump electrode is to be formed and (B) Al or Al alloy with which the pad electrode is formed, and functions as so-called current film for electrolytic plating. The metal thin film is also called base metal. Note that, the base metal may be a single layer of metal thin film, but is usually a layered film in which a plurality of metals are layered, for preventing the reaction between Au and Al or Al alloy, or other reasons. The base metal is prepared by sequentially layering TiW to have a thickness of approximately 0.2 μm and Au to have a thickness of 0.2 μm.

Next, photo resist is applied to the entire surface of the wafer. Then, photolithography is used to remove a predetermined portion of the photo resist on the wafer, namely a portion of the photo resist that is on the opening portion of the surface protection film.

With these steps, the semiconductor substrate 4 is formed. The semiconductor substrate 4 is a substrate to be plated in the next, plating step. Note that, the photo resist remaining on the wafer functions as a mask in the plating step, so as to deposit plating metal on the opening portion of the photo resist.

Further, the following will explain the plating step of forming a bump electrode on the semiconductor substrate 4 using Au plating. The electric field plating device 1 of the present embodiment carries out the plating step.

First, a cathode electrode of the electric field plating device 1 is connected to a predetermined position on the base metal that is layered on the wafer of the semiconductor substrate. Then, the semiconductor substrate 4 and the anode electrode 5 are immersed in the plating liquid 3 that fills the plating bath 2, in such a manner that the semiconductor substrate 4 and the anode electrode 5 substantially face each other in parallel. Further, the shielding plate 7 is inserted between the semiconductor substrate 4 and the anode electrode 5. The shielding plate 7 is made of an insulator having a circular opening section. The power source 6 applies a predetermined voltage across the semiconductor substrate 4 and the anode electrode 5, so as to deposit plating metal on a predetermined portion of the semiconductor substrate 4, namely, on the opening portion of the photo resist, by the electrolytic plating method.

The voltage applied across the semiconductor substrate 4 and the anode electrode 5 should be appropriately set based on the size of the semiconductor substrate 4, the speed of plating the semiconductor substrate 4, and the like. Further, a distance between the semiconductor substrate 4 and the anode electrode 5 is approximately 40 mm, and the shielding plate 7 is provided substantially at the midpoint of the semiconductor substrate 4 and the anode electrode 5. Further, the bump electrode deposited in the plating step has a height (namely, plating thickness) of approximately 18 μm, and the bump electrode has a size of approximately 50 μm×100 μm.

After the bump electrode is formed on the semiconductor substrate 4 in the plating step, the photo resist is removed, and then a needless portion of the base metal is removed using the bump electrode as a mask. Then, predetermined steps are carried out to complete the semiconductor integrated circuit.

With these steps, the bump electrode is formed on the semiconductor substrate 4 using gold (Au) plating. The electric field plating device 1 of the present embodiment is arranged so that the opening section of the shielding plate 7 has an optimum diameter so as to form the bump electrode having a uniform height.

In order to find the optimum diameter of the opening section of the shielding plate 7, variation in the plating thickness (height of the bump electrode) within the wafer was researched in the present embodiment, with respect to different diameters of the circular opening section of the shielding plate 7. Note that, a target height of the bump electrode was 18 μm.

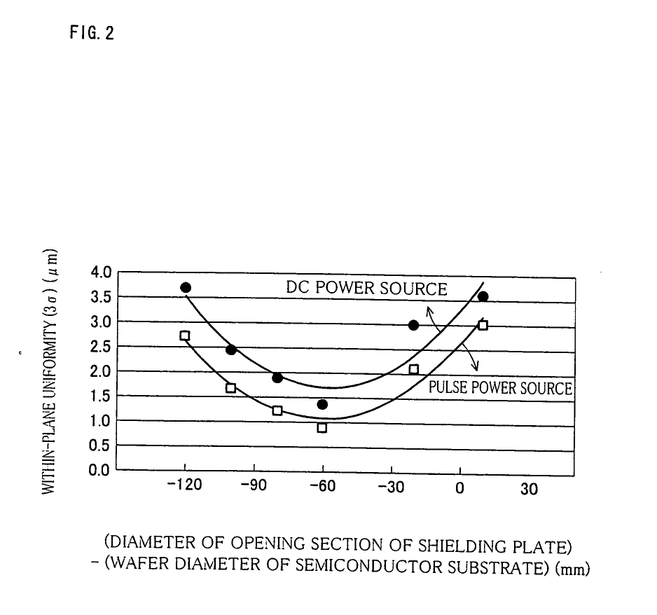

FIG. 2 shows results of the research. The horizontal axis indicates a difference (mm) between the diameter of the shielding plate 7 and a wafer diameter of the semiconductor substrate 4, and the vertical axis indicates the standard deviation (3σ) of the variation in the height of the bump electrode. Further, FIG. 2 shows cases where (A) a DC power source or (B) a pulse power source is used as the power source that applies a voltage across the semiconductor substrate 4 and the anode electrode 5.

FIG. 2 shows that, in the case where the DC power source is used, the variation (3σ) in the height of the bump electrode is the smallest, namely approximately 1.4 μm, when the diameter of the circular opening section is smaller than the wafer diameter by substantially 60 mm.

As described in BACKGROUND ART, the variation in the height of the bump electrode is preferably as small as possible in the packaging technique using the bump electrode, in order to obtain the strength for connecting the bump electrode with the packaging substrate. The tolerance for the variation in the height of the bump electrode has become smaller, as the semiconductor integrated circuit has miniaturized to have advanced function. At the product level, the practical tolerance for the variation in the height of the bump electrode is approximately 4 μm at most. Namely, the tolerance for the variation (3σ) in the height of the bump electrode is approximately ±2 μm.

According to FIG. 2, the condition that satisfies the tolerance is such that the diameter of the circular opening section of the shielding plate 7 is smaller than the wafer diameter of the semiconductor substrate 4 by approximately 30 mm to 90 mm. More preferably, the diameter of the circular opening section of the shielding plate 7 should be smaller than the wafer diameter of the semiconductor substrate 4 by approximately 45 mm to 75 mm, so as to improve the connecting strength.

Further, the foregoing explained the results in the case where the plating is carried out by applying a DC voltage to the semiconductor substrate 4 (cathode electrode) and the anode electrode 5. As shown in FIG. 2, similar results are obtained in the case where the plating is carried out by applying a pulse voltage, and the variation in the height of the bump electrode is the smallest when the diameter of the circular opening section is smaller than the wafer diameter substantially by 60 mm.

Note that, the pulse voltage applied here is such that an ON period is 80 msec, an OFF period is 20 msec, an applied period is 81 minutes, and an applied voltage is 0.4 mV. These results show that similar or better effects can be achieved in the case where a pulse voltage is applied to the cathode electrode and anode electrode as in the case where a DC voltage is applied.

Further, the foregoing explained an example where the bump electrode of gold (Au) is formed on the semiconductor substrate 4 which uses the silicon wafer having a diameter of six inches (approximately 150 mm). But, with an 8-inch (approximately 200 mm) wafer instead of the 6-inch (approximately 150 mm) wafer, it is confirmed that the variation within the bump electrode is the smallest when the diameter of the opening section of the shielding plate 7 is smaller than the wafer diameter by approximately 60 mm. It is also confirmed here that the variation (3σ) in the height of the bump electrode falls within the practical tolerance when the diameter of the circular opening section of the shielding plate 7 is smaller than the wafer diameter of the semiconductor substrate 4 by approximately 30 mm to 90 mm.

The foregoing results clearly show that the electric field plating device 1 can achieve the uniform plating thickness (namely, height of the bump electrode) by optimally setting the opening section of the shielding plate 7 so that the difference between the diameter of the opening section of the shielding plate 7 and the wafer diameter of the semiconductor substrate 4 is a predetermined value. The diameter of the opening section of the shielding plate 7 used in the electric field plating device 1 should be smaller than the wafer diameter of the semiconductor substrate 4 by approximately 30 mm to 90 mm, preferably by approximately 45 mm to 75 mm, and most preferably by 60 mm.

The diameter of the silicon wafer used for manufacturing a semiconductor integrated circuit is standardized by the inch size, such as 6 inches (approximately 150 mm) and 8 inches (approximately 200 mm). Here, it is revealed that the optimum value of the opening section of the shielding plate 7 is defined by the difference between the diameter of the opening section and the wafer diameter of the semiconductor substrate 4. With this, it becomes easy to obtain only one type of the shielding plate in which the diameter of the opening section is optimally set with respect to each wafer size. This eliminates the need for preparing many shielding plates 7 each having the opening section of a different diameter. Further, the shielding plate 7 has a fairly simple shape in which a circular opening section is provided to an insulator plate, thereby causing no extra cost for preparing the shielding plate 7.

If the plating is carried out by using the shielding plate 7 whose opening section has the diameter in accordance with the present invention, there is no need to change the size of the opening section during the plating, and there is no need to monitor electric resistance and its changes in the conductive layer that is formed on the surface of the wafer. This does not entail the cost of a device for monitoring the electric resistance and the cost of monitoring and adjusting. This remarkably reduces costs compared with the conventional technique.

Further, the electric field plating device 1 achieves the foregoing results in the condition such that the semiconductor substrate 4 and the anode electrode 5 are placed at a distance of approximately 40 mm and the shielding plate 7 is provided substantially at the midpoint between the semiconductor substrate 4 and the anode electrode 5. Strictly speaking, the optimum numerical range may change as the distance between the semiconductor substrate 4 and the shielding plate 7 changes.

However, if the electric field plating device 1 forms a bump electrode of a semiconductor device using gold (Au) plating, it is considered that the conditions such as the distance between the electrodes scarcely vary from one device to another. This is because the semiconductor substrate 4, as a substrate to be plated, substantially has the same size, and the plating bath is made as smaller as possible in response to demand for reducing plating liquid used therein because plating liquid of gold plating costs much.

As has been described, it is known in the electrolytic plating method that the plating is thicker on the peripheral portions of the substrate than on the central portion of the substrate because lines of electric force concentrate at peripheral portions of the substrate to be plated. To prevent this, suggested is a method to provide the shielding plate between the substrate to be plated and the anode electrode.

If the electric field plating method is used to manufacture a semiconductor integrated circuit, a silicon wafer used in the semiconductor substrate 4 generally has a circular shape. Thus, it is preferable that the opening section of the shielding plate 7 also has a circular shape, and (A) the center of the wafer which is the substrate to be plated, (B) the center of the opening section of the shielding plate 7, and (C) the center of the anode electrode 5 are substantially aligned. With this, the wafer can achieve good symmetric property with respect to the opening section, thereby preventing the concentration of the lines of electric forces at the peripheral portions of the wafer. This effectively reduces the variation in the growth rate of plating, namely the variation in the final plating thickness, on the entire surface of the wafer.

Note that, if the outer size of the shielding plate 7 is almost the same as the diameter of the wafer which is the substrate to be plated, for example, it is difficult to prevent the concentration of the lines of electric forces at the peripheral portions of the wafer, because of the lines of electric force that cover the outside of the shielding plate 7. Therefore, the size of the shielding plate 7 needs to be larger than the wafer diameter. The shielding plate 7 used in the present embodiment has an outer size of approximately 285 mm×280 mm, and is provided with the circular opening section at a predetermined position near the center of the shielding plate 7.

Further, a method to stir plating liquid or cause plating liquid to flow at constant speed is generally used in the electrolytic plating so as to retain a constant ion concentration of the plating metal in the vicinity of the surface of the wafer.

Here, a method to provide the shielding plate in contact with inner walls of the plating bath (for example, Japanese Unexamined Patent Publication No. 2000-195823, Tokukai 2000-195823; published on Jul. 14, 2000) is suggested. With this, however, at the portion where the shielding plate touches the inside walls of the plating bath, the flow of the plating liquid is obstructed and the plating liquid stagnates, thus causing variation in the plating speed. Further, foreign body mixed into the plating liquid tends to accumulate at the stagnated portion of the plating liquid. If the foreign body adheres to the surface of the substrate to be plated during plating processing, the adhered portion is abnormally plated.

For this reason, the electric field plating device 1 of the present embodiment is so arranged that a predetermined gap is provided between the shielding plate 7 and a bottom surface of the plating bath 2, thereby allowing substantially the same amount of plating liquid to flow at any portion of the gap. The outer shape of the shielding plate 7 is substantially the same as the internal shape of the plating bath that is sectioned orthogonal to the direction of liquid flow. The stagnation of the plating liquid and the accumulation of the foreign body are prevented in the plating bath 2 by providing the predetermined gap between the shielding plate 7 and the bottom surface of the plating bath 2 as described above.

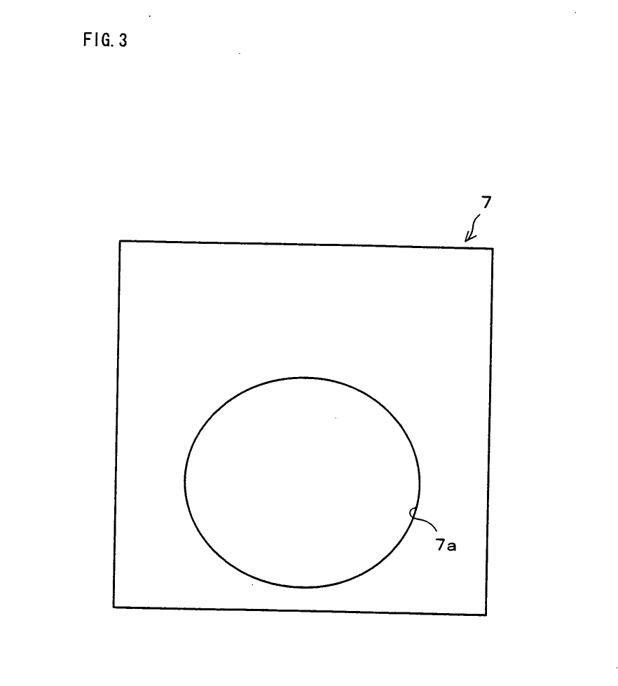

FIG. 3 is a plan view showing an example of the shielding plate 7 used in the electric field plating device 1. The opening section 7a of the shielding plate 7 has a diameter of approximately 90 mm, and a gap between the lower side of the shielding plate 7 and the bottom surface of the plating bath 2 is approximately 15 mm.

Note that, the foregoing explained an example where the plating method and plating device of the present invention are used for manufacturing the semiconductor integrated circuit on which the bump electrode is formed using gold plating. However, an ordinary plating device also needs to form a plating film having a uniform thickness on a substrate to be plated. Accordingly, the plating method and plating device of the present invention are not exclusively used for manufacturing a semiconductor integrated circuit, but may be applied to general plating processing.

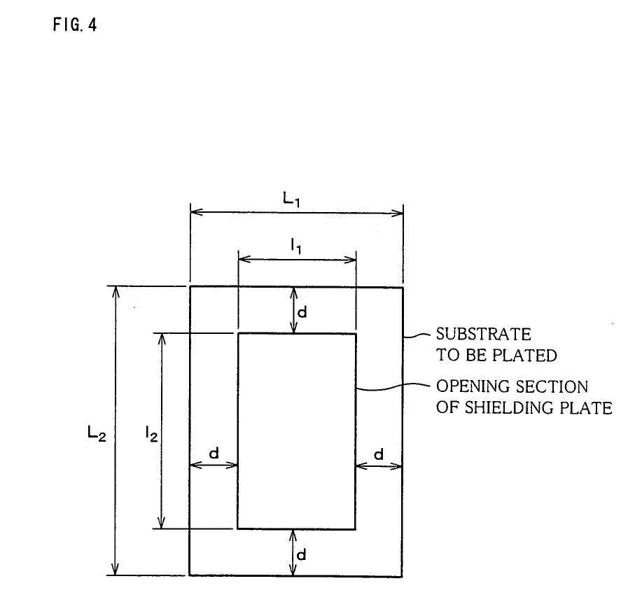

Further, in general plating processing, the substrate to be plated is not limited to have a circular shape such as the shape of the wafer of a semiconductor device. Accordingly, the opening section of the shielding plate needs to have a shape other than the circular shape. For example, when the substrate to be plated has a rectangular shape as shown in FIG. 4, the shielding plate should be arranged such that the opening section of the shielding plate also has a rectangular shape, and an outer edge of the opening section of the shielding plate is smaller than an outer edge of the substrate to be plated by a predetermined distance d.

When the substrate to be plated and the opening section of the shielding plate have the shapes as shown in FIG. 4, the uniformity of the thickness of the plating film formed on the substrate to be plated is improved most when a difference between the size of the substrate to be plated and the size of the opening section of the shielding plate, namely (L₁−I₁) and (L₂−I₂), is approximately 60 mm, assuming that the distance between the substrate to be plated and the shielding plate is the same as the above-explained distance between the semiconductor substrate 4 and the shielding plate 7.

Further, in the plating method and plating device of the present invention, the type of plating metal, etc., is not limited, and a metal other than Au may be used.

A plating method of the present invention that includes the steps of (i) causing a target substrate to be a cathode electrode, (ii) immersing the target substrate and an anode electrode in a plating liquid that fills a plating bath so that the target substrate and the anode electrode substantially face each other in parallel, and (iii) forming a plating film on the target substrate using an electrolytic plating method is arranged so that a shielding plate having an opening section is inserted between the target substrate and the anode electrode; and an outer edge of the opening section is smaller than an outer edge of the target substrate by a predetermined distance, the predetermined distance being set so that a difference between a size of the target substrate and a size of the opening section has an optimum value that enables the plating film to have a uniform thickness entirely on a surface of the target substrate.

Here, the present invention is based on the discovery as described below. In the plating method, in order to form a plating film having a uniform thickness on the entire surface of the substrate to be plated, an optimum value of the opening section of the shielding plate is given using a fixed value. The fixed value is a difference between the size of the substrate to be plated and the size of the opening section of the shielding plate, irrespective of the size of the outer edge of the substrate to be plated.

With this arrangement, the outer edge of the opening section of the shielding plate is smaller than the outer edge of the substrate to be plated by a predetermined distance, and the predetermined distance is set so that the difference between the size of the substrate to be plated and the size of the opening section is the fixed value. With this, special operation such as the size adjustment of the opening section is not required for preparing a shielding plate having an opening section whose size is optimally set with respect to a substrate to be plated whose size is specified. Therefore, it is possible to easily prepare the optimum shielding plate.

By carrying out the plating processing using the shielding plate having an opening section whose size is optimally set, it is possible to form a plating film having almost no variation in thickness within the substrate to be plated. Here, there is no need to monitor changes in electric resistance during the plating, or to adjust or replace the shielding plate, etc. This remarkably reduces the cost compared with the conventional art.

The plating method may be so arranged that the target substrate is a circular semiconductor substrate on which semiconductor integrated circuits are mounted, a bump electrode as the plating film being formed on the surface of the semiconductor substrate in the step (iii); and the opening section has a circular shape, a difference between a diameter of the semiconductor substrate and a diameter of the opening section being set to an optimum value that enables the bump electrode to have a uniform height entirely on the surface of the semiconductor substrate.

With this arrangement, it is possible to improve the uniformity of the height of the bump electrode within the entire semiconductor substrate in the manufacturing of a semiconductor integrated circuit, without providing to the plating device, means for monitoring changes in electric resistance of the conductive film, means for changing the size of the opening section of the shielding plate, and the like. This easily achieves the practical strength for connecting the bump electrode and the packaging substrate.

A plating device of the present invention that carries out the steps of (i) causing a target substrate to be a cathode electrode, (ii) immersing the target substrate and an anode electrode in a plating liquid that fills a plating bath so that the target substrate and the anode electrode substantially face each other in parallel, and (iii) forming a plating film on the target substrate using an electrolytic plating method is so arranged that a shielding plate having an opening section is inserted between the target substrate and the anode electrode; and an outer edge of the opening section is smaller than an outer edge of the target substrate by a predetermined distance, the predetermined distance being set so that a difference between a size of the target substrate and a size of the opening section has an optimum value that enables the plating film to have a uniform thickness entirely on a surface of the target substrate.

With this arrangement, it is possible to carry out plating processing using the foregoing plating method. Further, special operation such as the size adjustment of the opening section is not required for preparing a shielding plate having an opening section whose size is optimally set with respect to a substrate to be plated whose size is specified. Therefore, it is possible to easily prepare the optimum shielding plate.

By carrying out the plating processing using the shielding plate having an opening section whose size is optimally set, it is possible to form a plating film having almost no variation in thickness within the substrate to be plated. Here, there is no need to monitor changes in electric resistance during the plating, or to adjust or replace the shielding plate, etc. This remarkably reduces the cost compared with the conventional art.

The plating device may be so arranged that the target substrate is a circular semiconductor substrate on which semiconductor integrated circuits are mounted, a bump electrode as the plating film being formed on the surface of the semiconductor substrate in the step (iii); and the opening section has a circular shape, a difference between a diameter of the semiconductor substrate and a diameter of the opening section being set to an optimum value that enables the bump electrode to have a uniform height entirely on the surface of the semiconductor substrate.

With this arrangement, it is possible to improve the uniformity of the height of the bump electrode within the entire semiconductor substrate in the manufacturing of a semiconductor integrated circuit, without providing to the plating device, means for monitoring changes in electric resistance of the conductive film, means for changing the size of the opening section of the shielding plate, and the like. This easily achieves the practical strength for connecting the bump electrode and the packaging substrate.

The plating device is preferably arranged so that a difference between the diameter of the semiconductor substrate and the diameter of the opening section is not less than 30 mm and not more than 90 mm. The plating device is more preferably arranged so that a difference between the diameter of the semiconductor substrate and the diameter of the opening section is not less than 45 mm and not more than 75 mm.

With this arrangement, in the method for packaging a semiconductor integrated circuit using the bump electrode, it is possible to achieve the uniformity within the bump electrode so as to achieve the practical strength for packaging the bump electrode on the packaging substrate.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

By carrying out plating processing using a shielding plate having an opening section whose size is optimally set, the plating method and plating device of the present invention can form a plating film having almost no variation in thickness within a substrate to be plated, without increasing manufacturing costs.

1. A plating method that includes the steps of (i) causing a target substrate to be a cathode electrode, (ii) immersing the target substrate and an anode electrode in a plating liquid that fills a plating bath so that the target substrate and the anode electrode substantially face each other in parallel, and (iii) forming a plating film on the target substrate using an electrolytic plating method, wherein:
a shielding plate having an opening section is inserted between the target substrate and the anode electrode; and
an outer edge of the opening section is smaller than an outer edge of the target substrate by a predetermined distance, the predetermined distance being set so that a difference between a size of the target substrate and a size of the opening section has an optimum value that enables the plating film to have a uniform thickness entirely on a surface of the target substrate.

2. The plating method as set forth in claim 1, wherein:
the target substrate is a circular semiconductor substrate on which semiconductor integrated circuits are mounted, a bump electrode as the plating film being formed on the surface of the semiconductor substrate in the step (iii); and
the opening section has a circular shape, a difference between a diameter of the semiconductor substrate and a diameter of the opening section being set to an optimum value that enables the bump electrode to have a uniform height entirely on the surface of the semiconductor substrate.

3. The plating method as set forth in claim 2, wherein:
a difference between the diameter of the semiconductor substrate and the diameter of the opening section is not less than 30 mm and not more than 90 mm.

4. The plating method as set forth in claim 2, wherein:
a difference between the diameter of the semiconductor substrate and the diameter of the opening section is not less than 45 mm and not more than 75 mm.

5. The plating method as set forth in claim 1, wherein:
a pulse voltage is applied across the target substrate and the anode electrode.

6. The plating method as set forth in claim 1, wherein:
an outer size of the shielding plate is larger than an outer size of the target substrate.

7. The plating method as set forth in claim 1, wherein:
a gap is formed between the shielding plate and a bottom surface of the plating bath.

8. A plating device that carries out the steps of (i) causing a target substrate to be a cathode electrode, (ii) immersing the target substrate and an anode electrode in a plating liquid that fills a plating bath so that the target substrate and the anode electrode substantially face each other in parallel, and (iii) forming a plating film on the target substrate using an electrolytic plating method, wherein:
a shielding plate having an opening section is inserted between the target substrate and the anode electrode; and
an outer edge of the opening section is smaller than an outer edge of the target substrate by a predetermined distance, the predetermined distance being set so that a difference between a size of the target substrate and a size of the opening section has an optimum value that enables the plating film to have a uniform thickness entirely on a surface of the target substrate.

9. The plating device as set forth in claim 8, wherein:
the target substrate is a circular semiconductor substrate on which semiconductor integrated circuits are mounted, a bump electrode as the plating film being formed on the surface of the semiconductor substrate in the step (iii); and
the opening section has a circular shape, a difference between a diameter of the semiconductor substrate and a diameter of the opening section being set to an optimum value that enables the bump electrode to have a uniform height entirely on the surface of the semiconductor substrate.

10. The plating device as set forth in claim 9, wherein:
a difference between the diameter of the semiconductor substrate and the diameter of the opening section is not less than 30 mm and not more than 90 mm.

11. The plating device as set forth in claim 9, wherein:
a difference between the diameter of the semiconductor substrate and the diameter of the opening section is not less than 45 mm and not more than 75 mm.

12. The plating device as set forth in claim 8, wherein:
a pulse voltage is applied across the target substrate and the anode electrode.

13. The plating device as set forth in claim 8, wherein:
an outer size of the shielding plate is larger than an outer size of the target substrate.

14. The plating device as set forth in claim 8, wherein:
a gap is formed between the shielding plate and a bottom surface of the plating bath.
